(19) United States
(12) Patent Application Publication
(10) Pub. No.: US 2002/0094600 A1
(43) Pub. Date: Jul. 18, 2002

(54) Substrate processing apparatus and method for manufacturing a semiconductor device employing same

(75) Inventors: Yukinori Aburatani, Tokyo (JP); Toshimitsu Miyata, Tokyo (JP)

Correspondence Address: BACON & THOMAS, PLLC, 625 SLATERS LANE, FOURTH FLOOR, ALEXANDRIA, VA, 22314

(73) Assignee: Hitachi Kokusai Electric Inc., Tokyo (JP)

(21) Appl. No.: 10/046,255

(22) Filed: Jan. 16, 2002

(30) Foreign Application Priority Data
Jan. 17, 2001 (JP) 2001-008697

(51) Int. Cl. H01L 21/44

(52) U.S. Cl. 438/100; 118/500; 118/723 MR

(57) ABSTRACT

In a substrate processing apparatus including a processing chamber for forming a processing room, a susceptor for supporting a substrate to be processed and a susceptor rotating unit for rotating the susceptor, the susceptor rotating unit includes a permanent magnet coupled with the susceptor and an electromagnet coupled with the processing chamber, wherein there is a spacing between the permanent magnet and the electromagnet. In the substrate processing apparatus, the inner part of the processing chamber is isolated from the atmosphere of the susceptor by the spacing between the permanent magnet and the electromagnet; and the susceptor is directly rotated by rotating the permanent magnet under a magnetic field formed by the electromagnet.

### FIELD OF THE INVENTION

The present invention relates to a substrate processing apparatus and a method for manufacturing a semiconductor device employing same, e.g., a method for processing a semiconductor device on a substrate while revolving the substrate; and, more particularly, to a substrate processing apparatus and method capable of effectively performing a heat treatment process, e.g., an oxygen film or a metal film forming process on a semiconductor wafer on which a semiconductor integrated circuit having a semiconductor device is fabricated.

### DESCRIPTION OF THE PRIOR ART

There is a conventional cold-wall type single wafer chemical vapor deposition (CVD) apparatus (from now on referred to as a single wafer CVD apparatus) for forming an oxide film or a metal film on a wafer. The single wafer CVD apparatus includes a processing chamber accommodating a wafer to be processed, a susceptor for supporting the wafer within the processing chamber, a heating unit for heating the wafer supported by the susceptor, a gas head for supplying processing gases to the wafer supported by the susceptor and an exhaust port for exhausting the processing chamber.

There has been suggested a conventional single wafer CVD apparatus capable of revolving a susceptor supporting a wafer with a susceptor rotating unit for controlling thickness or quality of a CVD film uniformly over the entire surface thereof and for making processing gases contact with the entire surface thereof uniformly. U.S. Pat. No. 5,421,893 describes such a conventional CVD apparatus.

The single wafer CVD apparatus described in U.S. Pat. No. 5,421,893 discloses a pneumatic drive motor as a rotary device for rotating the susceptor, wherein a rotational shaft supporting the susceptor in a processing chamber is connected to the pneumatic drive motor by employing a magnetic coupling without mechanical contact therebetween, thereby hydromechanically isolating the inner part of the processing chamber in a vacuum state from the exterior part thereof under an atmospheric environment. Further, a position detection unit, e.g., a magnetic rotary encoder, having a magnetic sensor for detecting a position of a target body or a target portion of the target body is installed outside the magnetic coupling under the atmospheric environment. The target body and the target portion represent a body and a portion to be detected, respectively, by the position detection unit.

Since, however, the position detection unit is installed outside the magnetic coupling, there may occur a phenomenon that the position of the susceptor fixed to a passive coupling member is not accurately detected when there occurs a so-called mismatch (i.e., mismatch between an active coupling member and the passive coupling member) in the magnetic coupling.

If the position of the susceptor is not accurately detected, an extruded pin to lift the wafer from the susceptor deviates from a position corresponding to a through hole. As a result, the extruded pin may push the susceptor upward, entailing a malfunction of the extruded pin. Further, variation of the rotational speed of the susceptor results in a mismatch between a gas head and a heating unit which are rotating with respect to the wafer supported by the susceptor, thereby deteriorating the uniformity of the temperature and thickness over the wafer surface.

In order to overcome these problems, it is considered that the position of the susceptor should be detected by installing an optical position detection unit (e.g., optical rotary encoder) in a passive coupling member of a magnetic coupling disposed within a vacuum processing chamber. Since, however, a light emitting unit and a light receiving element are used as an optical position detection unit, there may be generated a spark; further since a disk is formed by using a resin, a thermal endurance thereof is deteriorated, wherein the disk has a slit attached thereto as a target body. Accordingly, the optical position detection unit cannot be installed in the processing chamber under vacuum and high temperature state.

### SUMMARY OF THE INVENTION

It is, therefore, an object of the present invention to provide a method for processing a substrate in a processing chamber while revolving the substrate and isolating the inner part of the processing chamber from outside the processing chamber.

In accordance with a preferred embodiment of the present invention, there is provided a substrate processing apparatus comprising: a processing chamber for forming a processing room; a susceptor for supporting a substrate to be processed; and a susceptor rotating unit for rotating the susceptor, wherein the susceptor rotating unit includes: a permanent magnet coupled with the susceptor; and an electromagnet coupled with the processing chamber, wherein there is a spacing between the permanent magnet and the electromagnet.

In the substrate processing apparatus, the inner part of the processing chamber is isolated from the atmosphere of the susceptor by the spacing between the permanent magnet and the electromagnet; and the susceptor is directly rotated by rotating the permanent magnet under a magnetic field formed by the electromagnet.

### BRIEF DESCRIPTION OF THE DRAWINGS

The above and other objects and features of the present invention will become apparent from the following description given in conjunction with the accompanying drawings, in which:

FIG. 1 illustrates a cross sectional view of a cold-wall type single wafer chemical vapor deposition (CVD) apparatus which is used in describing a process for forming a film of a semiconductor device manufacturing method in accordance with a preferred embodiment of the present invention;

FIG. 2 depicts an elevation partly in section of the CVD apparatus illustrated in FIG. 1; and

FIG. 3 shows a schematic cross sectional view of the CVD apparatus illustrated in FIG. 1, which is used in describing a wafer loading/unloading process therein.

### DETAILED DESCRIPTION OF THE PREFERRED EMBODIMENTS

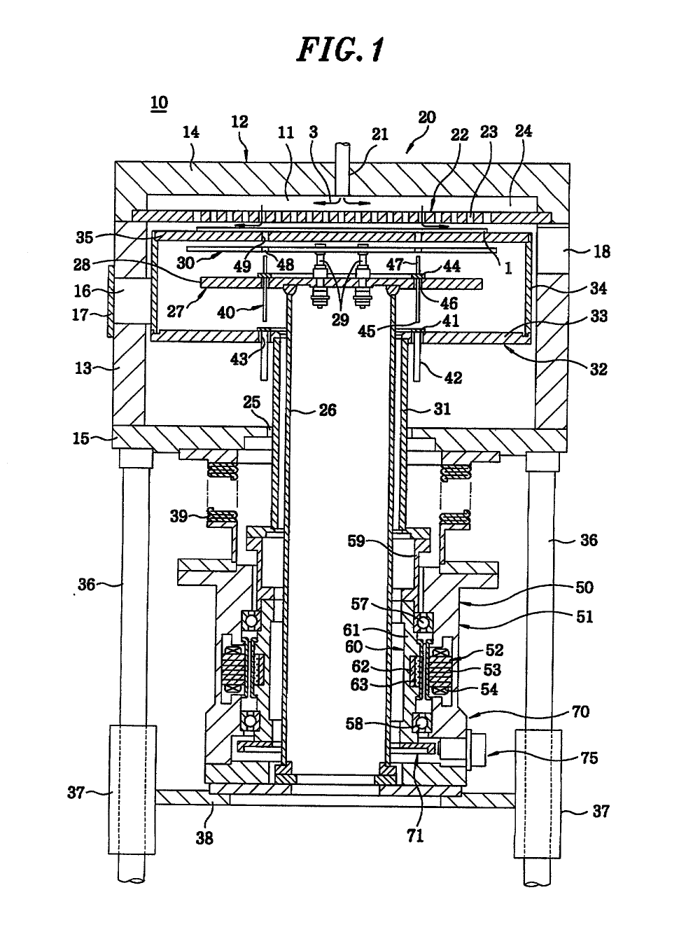

Preferred embodiments of the present invention will now be described in detail with reference to the accompanying drawings of FIGS. 1-3. In FIGS. 1-3, like reference numerals represent like parts.

FIG. 1 illustrates a cross sectional view of a cold-wall type single wafer chemical vapor deposition (CVD) apparatus 10 in accordance with a preferred embodiment of the present invention. The CVD apparatus 10 includes a processing chamber 12 forming a processing room 11 for processing a wafer (a semiconductor wafer) 1. The processing chamber 12 is assembled by a lower cup 13, an upper cup 14 and a lower cap 15, each of the upper and lower part of the processing chamber having a shape of sealed cylinder.

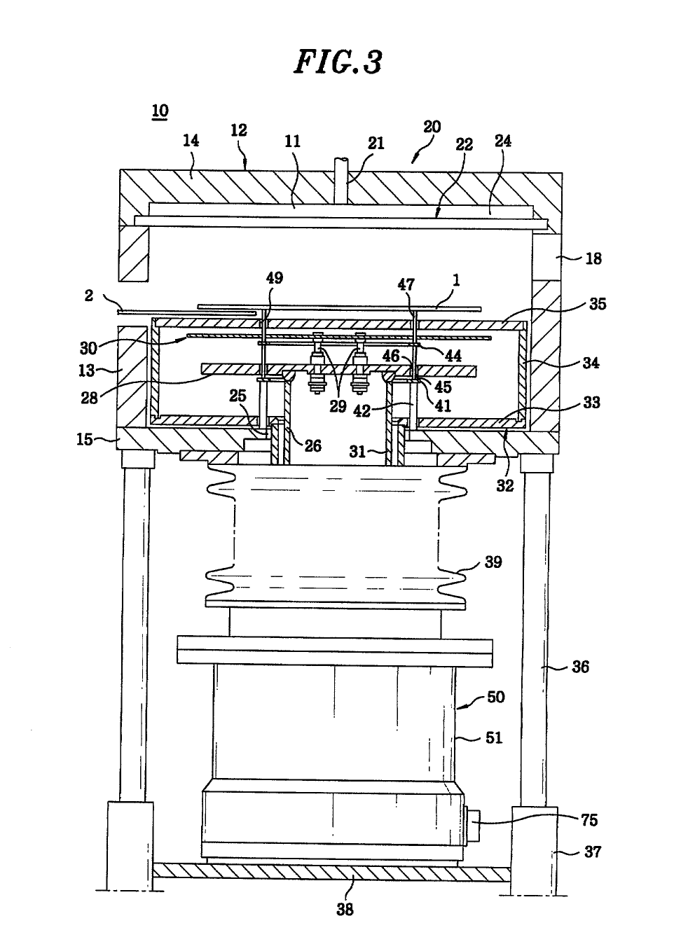

A wafer loading/unloading opening 16 is installed horizontally across the lower cup 13 of the chamber 12 in a middle height position thereof as depicted in FIG. 1. A wafer 1 can be loaded and unloaded into and from the processing room 11 by employing a wafer transfer unit (not shown) through the wafer loading/unloading opening 16. As illustrated in FIG. 3, the wafer 1 supported by a pair of tweezers 2 of the wafer transfer unit is loaded or unloaded with respect to the processing room 11 through the wafer loading/unloading opening 16.

An exhaust opening 18 is installed at an upper position of the wall of the lower cup 13 facing opposite to the wafer loading/unloading opening 16, wherein the exhaust opening 18 is hydrodynamically connected to the processing room and is connected to an exhausting unit (not shown), e.g., having a vacuum pump.

A gas head 20 is accommodated in the upper cup 14 of the processing chamber 12 as illustrated in FIG. 1. Namely, a gas inlet pipe 21 for supplying processing gases is inserted through the ceiling wall of the upper cup 14, wherein a gas supplying unit (not shown) for incorporating therein raw gases or purge gases is hydrodynamically connected to the gas inlet pipe 21.

A gas spray plate 22 of a disc shape is installed horizontally with a preset spacing from the gas inlet pipe 21 and a plurality of gas spray ports 23 are arranged concentrically with a predetermined interval over the entire surface of the plate 22 as shown in FIG. 1. Accordingly, the space above the gas spray plate 22 and that below the gas spray plate 22 are well ventilated. The space between the upper. cup 14 and the gas spray plate 22 forms a gas tank 24. The gas tank 24 sprays uniformly the processing gases incorporated therein from the gas inlet port 21 to the gas spray ports 23 in a shower shape.

A through hole 25 is installed in a circular shape at a center position of the lower cap 15 in the processing chamber 12. A supporting shaft 26 of a cylindrical shape is installed in the processing room 11 upward from below at a center line of the through hole 25. The supporting shaft 26 is designed to move up and down by employing an elevation unit, e.g., an air cylinder.

A heating unit 27 is concentrically arranged and fixed horizontally at a top position of the supporting shaft 26, wherein the heating unit 27 is moved up and down according to the movement of the supporting shaft 25. The heating unit 27 includes a supporting plate 28 of a disc shape, wherein the supporting plate 28 is fixed concentrically to a top opening portion of the supporting shaft 26. A multiplicity of electrodes 29 which also act as supporting members are installed on top of the supporting plate 28. The electrodes 29 support a heater 30 of a disc shape and are arranged in a bridge form. Electric wirings for the electrodes 29 (not shown) are inserted through an empty space of the supporting shaft 26.

A rotational shaft 31 is concentrically installed outside the supporting shaft 26 in the lower cap 15, wherein the rotational shaft 31 is formed in a hollow tube shape as shown in FIG. 1, the diameter thereof being larger than that of the supporting shaft 26. The rotational shaft 31 is moved up and down together with the supporting shaft 26 by employing an elevation unit (not shown), e.g., having an air cylinder.

A rotary drum 32 is concentrically arranged and fixed horizontally at a top position of the rotational shaft 31, wherein the rotary drum 32 includes a rotational flat plate 33 of a doughnut shape and a rotational cylinder 34 of a hollow tube shape, wherein an inner periphery of the rotational flat plate 33 is fixed to a top opening of the rotational shaft 31 and the rotational cylinder 34 is concentrically fixed to an exterior periphery of the top of the rotational flat plate 33. The susceptor 35 made of a silicon carbonate or an aluminum nitride forms a cap plate of the rotational cylinder 34 and the rotary drum 32, the susceptor 35 closing a top opening of the rotational cylinder 34.

As illustrated in FIG. 1, a wafer elevation unit 40 is installed in the rotary drum 32. The wafer elevation unit 40 includes an elevation ring (referred to also as a rotational side ring) 41 of a circle shape which is concentrically arranged with respect to the supporting shaft 26 on the rotational flat plate 33 of the rotary drum 32. A plurality of, e.g., three, pushing pins (referred to also as rotational side pins) 42 are arranged in a preset interval under the elevation ring 41 and are extruded vertically. Each of the rotational side pins 42 is arranged concentrically with the rotary cylinder 34 on the rotational flat plate 33, wherein each of the rotational side pins 42 is slidably inserted into a corresponding guide hole 43 which is vertically opened.

All the rotational side pins 42 have an identical length so that the rotational side ring 41 can be lifted in a horizontally balanced state and the identical length is set to correspond to a distance from the susceptor 35 to the lifted wafer. The bottom end of each of the rotational side pins 42 is set in such a way that it can land and take-off with respect to the bottom of the processing room 11, i.e., the top of the lower cap 15.

An elevation ring (referred to as a heater side ring) 44 of a circle shape is arranged concentrically with the supporting shaft 26 in the supporting plate 28 of the heating unit 27. A plurality of, e.g., three, extruded pins (referred to also as heater side pins) 45 are arranged in a preset interval to the peripheral direction under the heater side ring 44 and are extruded downward. Each of the heater side pins 45 is arranged concentrically with supporting shaft 26 on the supporting plate 28, wherein each of the heater side pins 42 is slidably inserted into a corresponding guide hole 46 which is vertically opened.

All the heater side pins 45 have an identical length so that the heater side ring 44 can be lifted in a horizontally balanced state and the bottom end thereof faces with the top surface of the rotational side ring 41 by way of an air gap. Namely, the rotational side ring 41 does not interfere with each of the heater side pins 45 while the rotary drum 32 is rotated.

A plurality of, e.g., three, extruded pins (referred to also as extruded parts) 47 are extruded upward and arranged in a preset interval to the peripheral direction on top of the heater side ring 44. Top ends of the extruded parts 47 face with through holes 48 of the heater 30 and through holes 49 of the susceptor 35.

All the extruded parts 47 have an identical length so that each of the extruded parts 47 goes through the through holes 48 of the heater 30 and the through holes 49 of the susceptor 35 successively and the wafer 1 mounted on the susceptor 35 is lifted in a horizontally balanced state. Further, the length of each of the extruded parts 47 is set in such a way that when the heater side ring 44 is mounted on the supporting plate 28, the top end of each of the extruded parts 47 does not touch with the surface of the heater 30. Namely, the extruded parts 47 do not interfere with the susceptor 35 and the heating operation of the heater 30 is not interfered while the rotary drum 32 is rotated.

As illustrated in FIG. 1, the chamber 12 is supported horizontally by a plurality of supports 36. Elevation blocks 37 are slidably inserted into corresponding supports 36, respectively. An elevation die 38 which is moved up and down by an elevator (not shown) having, e.g., an air cylinder is installed between the elevation blocks 37. A susceptor rotating unit 50 is installed over the elevation die 38. A bellows 39 is installed between the susceptor rotating unit 50 and the processing chamber 12 in such a way that the bellows 39 seals the exterior part of the rotational shaft 31.

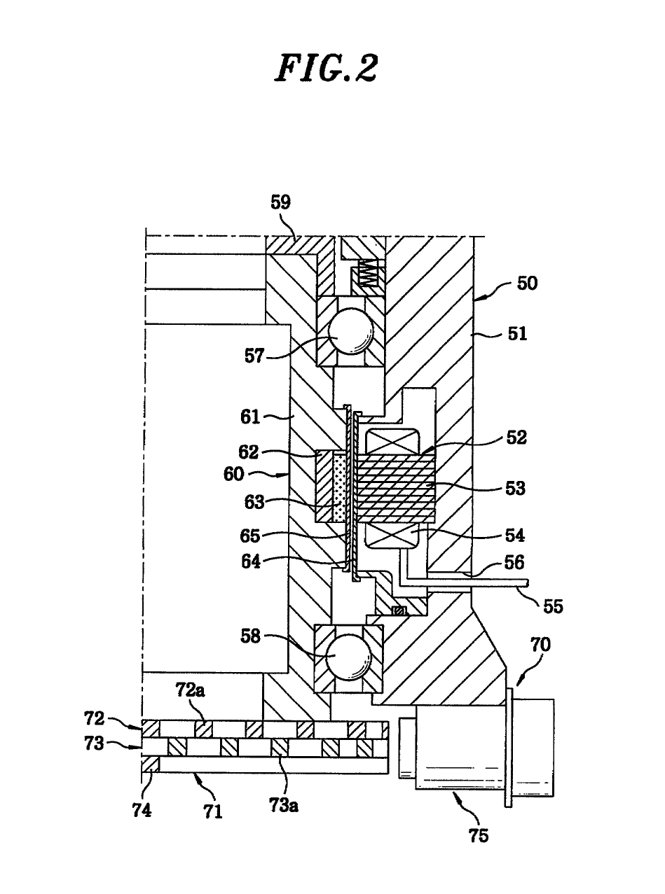

As depicted in FIGS. 1 and 2, there is used a brushless DC motor in the susceptor rotating unit 50 installed on the elevation die 38, wherein an output shaft of the motor is formed in a hollow shaft as the rotating shaft 31. The susceptor rotating unit 50 includes a housing 51 which is installed in a vertically upward direction on the elevation die 38. A stator 52 having an electromagnet coil is fixed on an inner periphery of the housing 51. The stator 52 is made by a winding coil (enamel coated Cu wire) 54 on a Fe core 53. A lead wire 55 is electrically connected to the winding coil 54 through a through hole 56 opened along the side wall of the housing 51. The stator 52 supplies an electric power to the winding coil 54 through the lead wire 55 from a driver (not shown) of the brushless DC motor, thereby forming a rotational magnetic field.

A rotor 60 is installed concentrically by way of an air gap, the rotor 60 facing to the stator 52. The rotor 60 is rotatably supported through ball bearings 57 and 58 to the housing 51. Namely, the rotor 60 includes a main body 61 of a hollow tube shape, a Fe core 62 and a plurality of permanent magnets 63, wherein the rotational shaft 31 is rotatably fixed to the main body 61 by using a bracket 59.

The core 62 is tightly coupled to the main body 61, wherein the plurality of permanent magnets 63 are fixed at a preset interval along an exterior periphery of the Fe core 62. There are formed a plurality of magnetic poles arranged in a circular direction by the Fe core 62 and the plurality of permanent magnets 63, wherein the magnetic flux of the permanent magnets 63 is cut by the rotational magnetic flux formed due to the stator 52, thereby resulting in revolution of the rotor 60.

The ball bearings 57 and 58 are installed in above and below the main body 61 of the rotor 60, respectively, wherein there is maintained a spacing in each of the ball bearings 57 and 58 to absorb the thermal expansion thereof. This spacing of each of the ball bearings 57 and 58 is set as about 5 μm to about 50 μm to absorb the thermal expansion and to suppress the fluctuation thereof. When the balls are pushed either toward an inner trace or an outer trace, the spacing of a ball bearing represents a spacing between balls and the trace other than the trace toward which the balls are pushed.

An exterior envelope member 64 and an inner envelope member 65 constituting a dual wall are installed in an inner periphery of the housing 51 and an exterior periphery of the main body 61, facing surfaces of the stator 52 and the rotor 60, respectively, wherein there is set an air gap between the exterior envelope member 64 and the inner envelope member 65. Each of the exterior envelope member 64 and the inner envelope member 65 is usually made of a non-magnetic stainless steel, wherein each of the exterior envelope member 64 and the inner envelope member 65 formed in a shape of thin hollow cylinder is confidentially and uniformly fixed by performing electron beam welding on the housing 51 and the main body 61 at an upper and a lower opening thereof.

Since each of the exterior envelope member 64 and the inner envelope member 65 is made of a non-magnetic thin stainless steel, spread of the magnetic flux thereof is suppressed so that the efficiency of the motor is maintained; the corrosion of the stator 52, the coil 54 and the permanent magnet of the rotor 60 is prevented; and the contamination of the processing room 11 due to, e.g., the contaminants of the coil 54 is also prevented. The exterior envelope member 64 envelopes to seal the stator 52, thereby isolating the stator 52 from the inner part of the processing room 11 maintained in a vacuum state.

As illustrated in FIGS. 1 and 2, there is installed a magnetic rotary encoder 70 in the susceptor rotating unit 50. The magnetic rotary encoder 70 includes a target ring 71 as a body to be detected, the target ring 71 being made of magnetic material, e.g., Fe, in a circular ring. A first tooth array 72 and a second tooth array 73 are formed adjacent to the periphery of the target ring 71 along a shaft direction thereof, wherein a plurality of teeth are arranged in each of the first tooth array 72 and the second tooth array 73. In a preferred embodiment of the present invention, the number of teeth installed in each of the target bodies 72a and 73a of the first tooth array 72 and the second tooth array 73 is 512, wherein there is a phase difference (position difference in the peripheral direction thereof) of a half-tooth between the first tooth array 72 and the second tooth array 73.

In order to increase resolution of the magnetic rotary encoder 70, it is necessary to increase the number of the teeth as the target bodies. Since, however, if the number of the teeth is simply increased, the diameter of the ring 71 should be increased. In the preferred embodiment of the present invention, the resolution of the magnetic rotary encoder 70 is increased by increasing the number of teeth without increasing the diameter of the ring 71 by installing the first tooth array 72 and the second tooth array 73.

In this case, since a reversal of the ring can be detected, a reversal of the brushless DC motor, i.e., a reversal of the susceptor rotating unit 50 can be avoided. This effect can be also obtained in a magnetic sensor 75 by fabricating the first tooth array 72 and the second tooth array 73 as same tooth array and by setting a first detector corresponding to the first tooth array 72 and a second detector corresponding to the second tooth array 73 with a half-pitch difference.

There is installed a reference tooth 74 representing a reference position at opposite side of the first tooth array 72 and the second tooth array 73, the phase of the reference tooth 74 corresponds to a tooth 72a of the first tooth array 72. Since it is possible to monitor a home position (zero point) of the ring 71 by detecting the reference tooth 74 once per every revolution thereof, a current position of the susceptor 35 within a range of 360 can be recognized by detecting the tooth 72a of the first tooth array 72.

A magnetic sensor 75 to detect a tooth of the ring 71 is installed at opposite side of the ring 71 of the housing 51. The magnetic sensor 75 is installed corresponding to the first tooth array 72, the second tooth array 73 and the reference tooth 74, wherein the spacing (sensor gap) between a probe of the magnetic sensor 75 and the exterior periphery of the ring 71 ranges about 0.06 mm to about 0.17 mm. This value range of the spacing is obtained when the susceptor 35 is rotated with about 30 rpm.

In order to render thickness of a film deposited on the wafer 1 more uniform, it is preferable that the susceptor 35 is rotated with a higher rotational speed (e.g., about 1000 rpm). However, when the susceptor 35 is rotated in a higher rotational speed, strong centrifugal force may be applied on the sussecptr 35 or the rotary drum 32, thereby entailing a shake in the rotational shaft 31. In order to prevent the ring 71 from being brought into contact with the magnetic sensor 75 due to this shake, when the susceptor 35 is rotated in a higher rotational speed, it is preferable that the spacing ranges about 0.06 mm to about 0.35 mm; and more preferably about 0.06 mm to about 0.25 mm in view of detection sensitivity of the encoder 70.

The magnetic sensor 75 detects a variation of magnetic flux induced by the revolution of the ring 71 facing to the magnetic sensor 75 by employing a magnetic resistance element. The detection result of the magnetic sensor 75 is sent to a driver of the brushless DC motor, i.e., the driver of the susceptor rotating unit 50 and then used therein in forming a rotational magnetic field and sent to a position recognition unit of a controller (not shown) of the susceptor rotating unit 50, the detection result being used in position recognition therefor.

From now on, film forming processes in a semiconductor device manufacturing method in accordance with a preferred embodiment of the present invention will be described based on the description of a cold-wall type single wafer CVD apparatus 10 in accordance with preferred embodiments of the present invention described in the above.

As illustrated in FIG. 3, when a wafer is loaded or unloaded, the rotary drum 32 and the heating unit 27 are moved down to corresponding lower limit positions, respectively, by the rotational shaft 31 and the supporting shaft 26. Then, the lower end of the rotational side pin 42 of the wafer elevation unit 40 contacts with bottom of the processing room 11, i.e., top of the lower cap 15. This results in relative elevation of the rotational side ring 41 with respect to the rotary drum 32 and the heating unit 27. The elevated rotational ring 41 pushes up the heater side pin 45, thereby lifting up the heater side ring 44.

If the heater side ring 44 is lifted up, three extruded pins 47 installed on the heater side ring 44 pass through the through hole 48 of the heater 30 and the through hole 49 of the susceptor 35. Then, the extruded pins 47 push up the wafer 1 mounted on the susceptor 35, thereby lifting up the wafer 1 from the susceptor 35.

When the wafer 1 is lifted up above the top of the susceptor 35 by employing the wafer elevation unit 40, there is formed an insertion spacing between the bottom of the wafer 1 and the top of the susceptor 35 and the pair of tweezers 2 of a fork shape in a wafer transfer unit (not shown) is inserted from the wafer loading/unloading opening 16 into the insertion spacing for the wafer 1. The wafer 1 is mounted and transferred by elevating the pair of tweezers 2. The wafer 1 mounted on the pair of tweezers 2 is retired from the wafer loading/unloading opening 16, thereby unloading the wafer 1 from the processing room 11. The wafer transfer unit unloaded the wafer 1 by using the pair of tweezers 2 mounts and transfers the wafer 1 to a wafer accommodating part (not shown) for accommodating, e.g., an empty wafer cassette outside the processing room 11.

The wafer transfer unit takes a wafer to be processed next from the wafer accommodating part (not shown), e.g., a wafer cassette having wafers by employing the pair of tweezers 2 and then loads the wafer 1 into the processing room 11 through the wafer loading/unloading opening 16.

The pair of tweezers 2 carries the wafer 1 above the susceptor 35 at a corresponding position where the center of the wafer 1 coincides with the center of the susceptor 35. After the wafer 1 is carried to the corresponding position, the pair of tweezers 2 slightly moves down to thereby transfer and mount the wafer 1 on the susceptor 35. Then, the pair of tweezers 2 is retrieved from the wafer loading/unloading opening 16 to outside the processing room 11. If the pair of tweezers 2 is retrieved from the processing room 11, the wafer loading/unloading opening 16 is closed by a gate valve 17.

If the gate valve 17 is closed, the rotary drum 32 and the heating unit 27 are elevated by the elevation die 38 through the rotational shaft 31 and the supporting shaft 26. In the beginning of the elevation of the rotational shaft 31, rotational side pin 42 protrudes onto bottom of the processing room 11, i.e., top of the lower cap 15. As a result, the heater side pin 45 is mounted on the rotational side ring 41. The wafer 1 supported by the extruded part 47 of the rotational side ring 41 slowly moves down as the rotary drum 32 moves up.

When the rotational side pin 42 is separated from the bottom of the processing room 11, the heater side ring 44 moves down. Then, the extruded part 47 is inserted into the susceptor 35 from down to upward direction. As a result, the wafer 1 is safely mounted on the susceptor 35 as shown in FIG. 1. The rotational shaft 31 and the supporting shaft 26 are stopped when the top end of the extruded part 47 is stopped at a position near the heater 30.

Meanwhile, the processing room 11 is exhausted by an exhausting unit (not shown) connected to the exhaust opening 18. In this case, the inner part of the processing room 11 in a vacuum state is isolated from the outside thereof under an atmospheric pressure by the bellows 39. The vacuum state of the susceptor rotating unit 50 in the bellows is isolated from the atmospheric environment of the exterior envelope member 64 and the exterior races of ball bearings 57 and 58.

The rotary drum 32 is revolved by the susceptor rotating unit 50 through the rotating shaft 31. Namely, if the susceptor rotating unit 50 is activated, rotational magnetic field of the stator 52 cuts magnetic field of magnetic poles of the rotor 60. As a result, the rotor 60 is revolved and then the rotary drum 32 is revolved by the rotational shaft 31 fixed to the rotor 60. In this case, a position of the rotor 60 is detected in a preset time interval and a detected position signal is sent to the driver. Based on this detected position signal, rotational magnetic field is formed and at the same time, the rotational speed of the rotary drum 32 is controlled in accordance with a command of a controller (not shown).

Since the rotational side pin 42 is separated from the bottom of the processing room 11 and the heater side pin 45 is separated from the rotational side ring 41 while the rotary drum 32 is revolved, the revolution of the rotary drum 32 is not prevented by the wafer elevation unit 40 and the heater unit 27 is maintained in a static state. Namely, in the wafer elevation unit 40, the rotational side ring 41 is revolved together with the rotary drum 32 while the heater side ring 44 is stopped together with the heater unit 27.

When an exhaust rate through the exhaust opening 18 and the revolution operation of the rotary drum 32 are stabilized, a processing gas 3 is fed into the gas inlet pipe 21 as illustrated by arrows of FIG. 1. The processing gas 3 are flown into a gas tank 24 with the help of the exhaust force of the exhaust opening 18 applied to the gas tank 24 and at the same time, the processing gas 3 is diffused toward a radial direction thereof. As a result, the gas 3 is sprayed on the wafer 1 in a shower shape through the gas spray ports 23 of the gas spray plate 22. The sprayed gas is then exhausted with the help of the suction force induced through the exhaust opening 18.

In this case, since the wafer 1 on the susceptor 35 supported by the rotary drum 32 is rotated, the processing gas 3 is sprayed uniformly on entire surface of the wafer 1 in a shower shape. Since the processing gas 3 contacts with the surface of the wafer 1 uniformly, thickness and quality of a CVD film formed on the wafer 1 by the processing gas 3 will be uniform over the entire surface of the wafer 1.

Further, the heater unit 27 supported by the supporting shaft 26 is not revolved while the wafer 1 is revolved by the rotary drum 32. As a result, the temperature distribution of the wafer 1 heated by the heater unit 27 becomes uniform throughout the entire surface thereof. Since the temperature distribution of the wafer 1 is controlled to be uniform over the entire surface thereof, thickness and quality of a CVD film formed on the wafer 1 through a thermo-chemical reaction therein can be uniformly controlled.

After a predetermined processing time is lapsed, the operation of the susceptor rotating unit 50 stops. In this case, since the rotation position of the susceptor 35, i.e., the position of the rotor 60 is detected frequently by the magnetic rotary encoder 70 installed in the susceptor rotating unit 50, the susceptor 35 can be stopped at a preset rotational position. Namely, the through hole 48 of the extruded part 47 and the through hole 49 of the susceptor 35 coincide with each other accurately with good reproducibility.

When the operation of the susceptor rotating unit 50 is stopped, the rotary drum 32 and the heating unit 27 are moved down to the loading/unloading position by the elevation die 38 connected to the rotational shaft 31 and the supporting shaft 26. As described in the above, when the rotational side pin 42 of the elevation unit 40 protrudes onto the bottom of the processing room 11 during downward movement of the rotary drum 32 and the heating unit 27, the heater side pin 45 protrudes onto the rotational side ring 41, thereby rendering the wafer elevation unit 40 to lift up the wafer 1 above the top of the susceptor 35. In this case, the through hole 48 of the extruded part 47 and the heater 30 and the through hole 49 of the susceptor 35 coincide with each other accurately with good reproducibility. Accordingly, no errors are made while the extruded part 47 lifts up the susceptor 35 and the heater 30.

Procedures described in the above are repeated, thereby forming a CVD film on the wafer 1 by the single wafer CVD apparatus 10. Meanwhile, instead of directly lifting up the wafer by the wafer elevation unit, the center part of the susceptor may be pushed up to thereby lifting up the wafer from the periphery portion of the susceptor 35. The substrate is not limited to the wafer.

Further, the substrate may be a glass substrate or a liquid panel used in manufacturing procedures of an LCD apparatus. The apparatus of present invention is not limited to the CVD apparatus, but may be applied on various substrate processing units, e.g., a dry etching unit.

In accordance with the preferred embodiment of the present invention, the following effects can be produced.

(1) The susceptor rotating unit includes a stator having an electromagnet installed at the side of the chamber and a rotor having a permanent magnet installed at the side of the susceptor, wherein a predetermined spacing or gap is maintained between the stator and the rotor. As a result, a magnetic field is formed due to the stator so that the rotor becomes revolved. Then, by the rotation of the rotor, the susceptor is also revolved. As such, it is possible in accordance with the present invention to precisely revolve the susceptor without using a conventional magnet coupling which frequently involves a mismatch.

(2) Since an exterior envelope member is disposed at an inner trace surface of the rotor in the susceptor rotating unit, the atmosphere of the susceptor side is isolated from that of the chamber side. Accordingly, a process room prepared at the side of the susceptor can be maintained in a vacuum state while the susceptor is revolving. As a result, the efficiency and the reliability of a film forming process performed in the processing room can be greatly increased and the processing room can be protected from contaminants including, e.g., a dust from the electromagnet.

(3) The exterior envelope member and an interior envelope member, which compose a dual wall between the stator and the rotor, are respectively fixed to an inner trace surface of the housing and an exterior trace surface of the main body in such a manner that the exterior and the interior envelope member face each other with an air gap maintained therebetween. As a result, the electromagnet of the stator and the permanent magnet of the rotor can be protected from processing gas and corrosions, so that durability of the susceptor rotating unit can be considerably improved.

(4) The exterior and the interior envelope member are made of thin stainless steels and are uniformly installed around the inner trace surface of the housing and the exterior trace surface of the main body, respectively, by using an electron beam welding technique. Thus, a minute air gap can be formed between the exterior and the interior envelope member so that spread of the magnetic flux which frequently leads to a deterioration of the motor efficiency can be effectively prevented. As a result, the efficiency of the susceptor rotating unit can be further increased.

(5) A ring composed of a magnetic substance having a plurality of teeth formed at an outer periphery thereof is installed at the side of the susceptor, the plurality of teeth functioning as portions to be detected, and a magnetic sensor for detecting the teeth is prepared at the side of the chamber. By such a configuration, a rotation position of the susceptor can be exactly estimated and thus the susceptor can be successfully stopped at a desired position. Accordingly, an extruded pin for lifting up a wafer can be engaged with a through hole of the susceptor and that of the heater such that a failure in lifting up the wafer can be largely diminished.

(6) By setting a spacing of about 0.06 to 0.35 mm between the ring and the magnetic sensor, interference between the ring and the magnetic sensor is prevented while the detection sensitivity of the magnetic rotary encoder is increased to a maximum level. Thus, the rotation position of the susceptor can be more effectively controlled.

(7) The ring to be detected by the magnetic rotary encoder does not involve a spark, which is frequently found in a floodlight unit and a light receiving unit of an optical rotary encoder. Further, the ring features a high thermal endurance. Accordingly, the ring can be maintained in the vacuum state without suffering from any damage so that the position of the susceptor can be precisely detected.

(8) By allowing the susceptor to revolve while fixing the heating unit, the wafer revolved by the susceptor and heated by the heating unit is controlled to have a uniform temperature distribution throughout an overall surface thereof. Accordingly, a CVD film formed on the surface of the wafer through a thermo-chemical reaction can also be controlled to have a uniform thickness and a uniform film quality.

(9) By precisely controlling the rotation of the susceptor through the use of the susceptor rotating unit and the magnetic rotary encoder, variations of the rotation speed and a non-uniformity of the rotation can be prevented. Accordingly, a temperature distribution on the overall surface of the wafer can be uniformly adjusted.

(10) By fixing the heating unit so as not to revolve, a heater and cables thereof can be installed within the heating unit.

While the present invention has been described with respect to certain preferred embodiments only, other modifications and variations may be made without departing from the sprit and scope of the present invention as set forth in the following claims.

What is claimed is:

1. A substrate processing apparatus comprising:
a processing chamber forming a processing room;
a susceptor for supporting a substrate to be processed; and
a susceptor rotating unit for rotating the susceptor, wherein the susceptor rotating unit includes:
a permanent magnet coupled with the susceptor; and
an electromagnet coupled with the processing chamber, wherein there is a spacing between the permanent magnet and the electromagnet.

2. The apparatus of claim 1, wherein a magnetic target body to be detected is installed at a side of the susceptor and a magnetic sensor to detect the magnetic target body is installed at a side of the chamber, the magnetic target body having a plurality of target portions formed thereon.

3. The apparatus of claim 1, wherein at least a portion of the permanent magnet and the electromagnet exposed to the processing room is covered with an envelope member.

4. The apparatus of claim 2, wherein at least a portion of the permanent magnet and the electromagnet exposed to the processing room is covered with an envelope member.

5. A method for manufacturing a semiconductor device employing a substrate processing apparatus comprising:
a processing chamber for forming a processing room;
a susceptor for supporting a substrate to be processed in the processing room; and
a susceptor rotating unit for rotating the susceptor, wherein the susceptor rotating unit having a permanent magnet coupled with the susceptor and an electromagnet coupled with the processing chamber, a spacing being formed between the permanent magnet and the electromagnet,
wherein a substrate processing is executed on the substrate while revolving the susceptor by the susceptor rotating unit.
